(19) United States
(12) Patent Application Publication
(10) Pub. No.: US 2009/0296324 A1
(43) Pub. Date: Dec. 3, 2009

(54) COVER LATCHING MECHANISM FOR ELECTRONIC DEVICE

(75) Inventors: MU-WEN YANG, Shindian (TW); CHIH-CHIANG CHANG, Shindian (TW); ZHENG SHI, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/345,365

(22) Filed: Dec. 29, 2008

(30) Foreign Application Priority Data
May 30, 2008 (CN) 200810301876.4

(51) Int. Cl. H05K 7/00

(52) U.S. Cl. 361/679.01

(57) ABSTRACT

A cover latching mechanism (100) for an electronic device includes a housing (30), a cover (50), and a mounting member (70) interconnecting the housing and the cover. The housing has a hinge portion (358) and a latching portion (355) formed thereon, and defines an opening (351) between the hinge portion and the latching portion. The cover has a connecting portion (53) and a locking portion (55) respectively formed at opposite ends of the cover. The locking portion engages with the latching portion of the housing to secure the cover in a closed position. The mounting member interconnects the hinge portion and the connecting portion to enable the cover to rotatate from a first position to the closed position.

### BACKGROUND

1. Field of the Invention

The present invention generally relates to cover latching mechanisms, specifically to cover latching mechanisms for electronic devices, such as mobile phones.

2. Description of Related Art

With the development of the technology of information processing, portable electronic devices such as digital cameras, mp3 players, video cameras, mobile phones, and personal digital assistants (PDAs) are now in widespread use. Memory cards are important elements to store data and applications in such portable electronic devices.

In some electronic devices, the memory cards are received in the housings of the electronic devices. The memory card has a first electronic interface element. The housing of the electronic device has an opening in a wall thereof. A second electronic interface element is provided in the housing and exposed by the opening. When the memory card is used, the first electronic interface element is inserted into the second electronic interface element through the opening. This enables data to be transferred among variable electronic devices. However, when no memory card is connected to the electronic device, the second electronic interface element of the electronic device is exposed to the environment and liable to be polluted by dust and/or water. Consequently, the performance of the second electronic interface element is liable to be degraded.

Therefore, there is room for improvement within the art.

### BRIEF DESCRIPTION OF THE DRAWINGS

Many aspects of the present cover latching mechanism can be better understood with reference to the following drawings. The components in the drawings are not necessarily drawn to scale, the emphasis instead being placed upon clearly illustrating the principles of the present cover latching mechanism. Moreover, in the drawings, like reference numerals designate corresponding parts throughout the several views.

FIG. 1 is an explored, isometric view of a cover latching mechanism, in accordance with an exemplary embodiment.

FIG. 2 is similar to FIG. 1, but viewed from another angle.

FIG. 3 is an assembled, isometric view of the cover latching mechanism shown in FIG. 1, showing the cover in a closed state.

FIG. 4 is an assembled, isometric view of the cover latching mechanism shown in FIG. 1, showing the cover in an open state.

### DETAILED DESCRIPTION OF THE EMBODIMENTS

The present cover latching mechanism is suitable for electronic devices, such as mobile phones, personal digital assistants (PDAs), and the like. Other applications with a similar use for the cover latching mechanism employed can also be found.

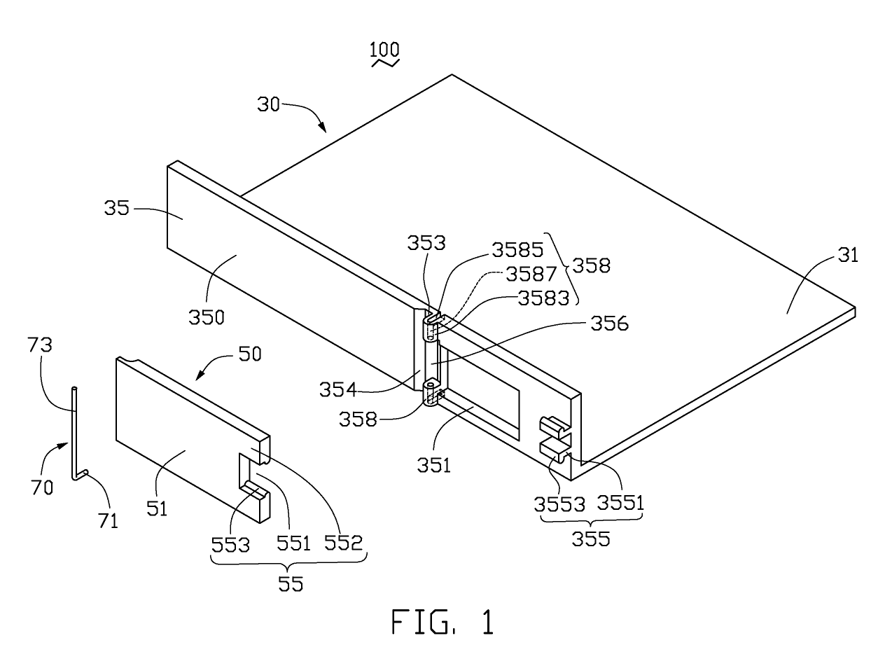

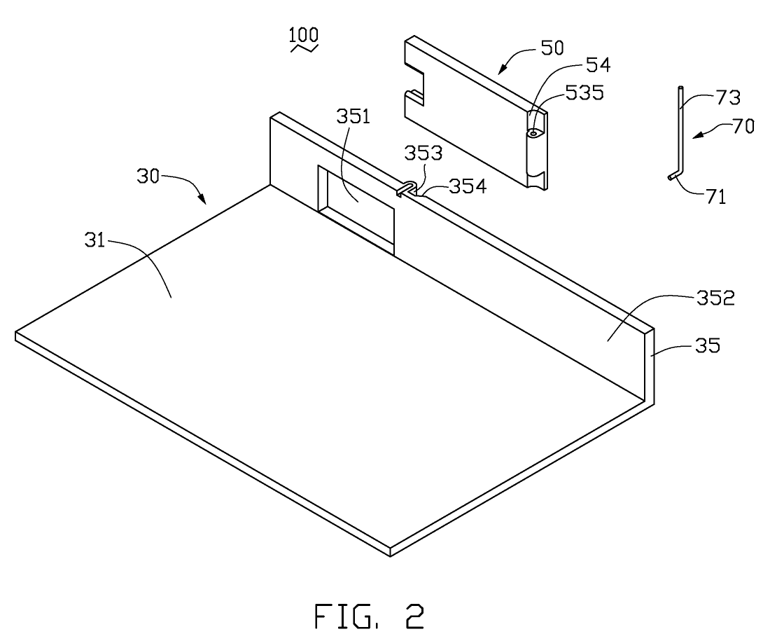

FIGS. 1 and 2 show a cover latching mechanism 100 for an electronic device including a housing 30, a cover 50, and a mounting member 70 interconnecting the housing 30 and the cover 50. The cover 50 is rotatable relative to the housing 30 by the mounting member 70.

The housing 30 has a bottom board 31 and a side wall 35 perpendicularly extending from an edge of the bottom board 31. The side wall 35 has an outer surface 350 and an inner surface 352, and defines an opening 351. Two latching portions 355 and a hinge portion 358 are respectively formed at two opposite sides of the opening 351. Each latching portion 355 is hook-shaped, and has a body 3551 perpendicularly extending from the outer surface 350 and a projection 3553 formed at a distal end thereof. The two projections 3553 extend away from each other. The hinge portion 358 includes two barrels 3583 and forms a first receiving portion 356 therebetween. Each barrel 3583 defines an axle hole 3587 therethrough and a pin hole 3585 in one side thereof. The axle holes 3587 communicate with the pin holes 3585. The side wall 35 defines a slot 353 in the outer surface 350 adjacent to the hinge portion 358 and forms a sloped surface 354.

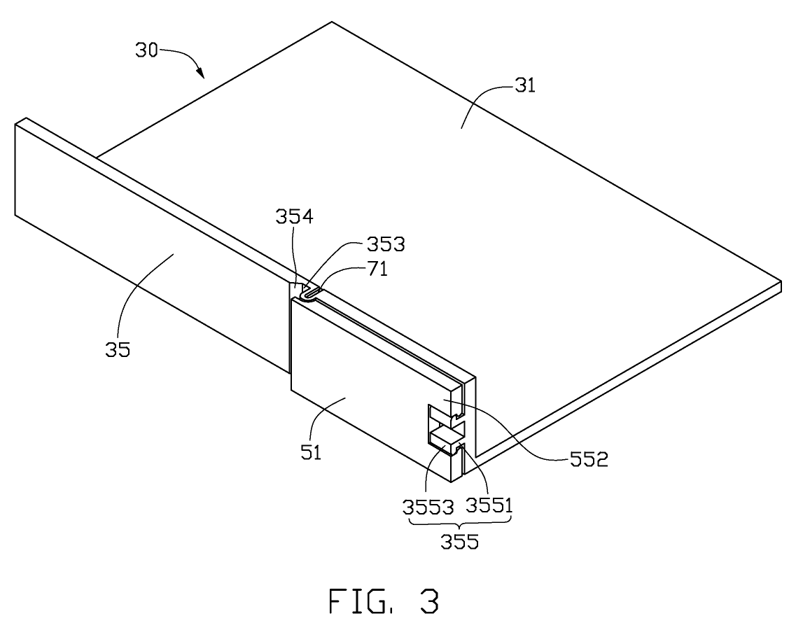

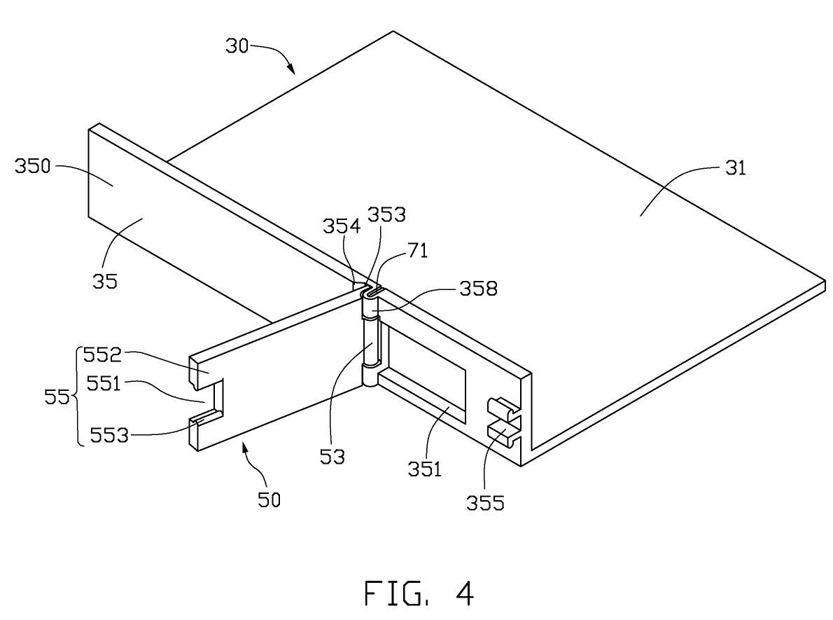

Also referring to FIGS. 3 and 4, the cover 50 has a cover body 51, a connecting portion 53 and a locking portion 55 respectively provided at two opposite ends of the cover body 51. The connecting portion 53 is barrel-shaped and is formed towards a center of an end of the cover body 51. Two second receiving portions 54 are defined towards two ends of the connecting portion 53. The connecting portion 53 defines an axle hole 535. The connecting portion 53 is configured for being receivable in the first receiving portion 356 of the housing 30, and the two barrels 3583 of the housing 30 are configured for being respectively received in the two second receiving portions 54, so the three axle holes 3587, 535 are coaxial. The locking portion 55 includes two arms 552 respectively extending from two ends of one side of the cover body 51 to define a cutout 551, therebetween. Each arm 552 has a projection 553 extending into the cutout 551. The two projections 553 face towards each other. Each latching portion 355 is configured for engaging a cutout 551.The projection 3553 of each latching portion 355 is configured for resisting a corresponding projection 553.

The mounting member 70 is L-shaped, and includes an axle 73 and a positioning pin 71 perpendicularly extending from a distal end of the axle 73. The axle 73 is configured for insertion into the axle holes 3587 and the axle holes 535 of the connecting portion 53, thereby rotatably mounting the cover 50 to the housing 30. The positioning pin 71 is configured for receiving in the pin hole 3585 of the hinge portion 358.

Referring to FIGS. 3-4, when the cover 50 is closed, the cover 50 is secured in the closed position by the projections 3553 of the latching portion 355 gripping the projections 553 of the locking portions 55. The secured cover 50 prevents dust and/or water from entering the electronic device through the opening 351. When opening the cover 50, the locking portion 55 is forced to disengage with the latching portion 355 and the cover 50 is rotated away from the side wall 35 of the housing 30 to expose the opening 351. The end with the connecting portion 53 of the cover 50 may be rotated into the slot 353 of the housing 30 until the cover body 51 abuts against the sloped surface 354.

It should be understood that the barrels 3583 of the hinge portion 358 may be one or more than two. The latching portion 355 may be one.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A cover latching mechanism for an electronic device, comprising:
a housing having a hinge portion and a latching portion formed thereon, and defining an opening between the hinge portion and the latching portion;
a cover having a connecting portion and a locking portion respectively formed at opposite ends of the cover, the locking portion engaging with the latching portion of the housing to secure the cover in a closed position; and
a mounting member interconnecting the hinge portion and the connecting portion to enable the cover to rotatate from a first position to the closed position.

2. The cover latching mechanism of claim 1, wherein the housing defines a sloped slot in an outer surface and adjacent to the hinge portion.

3. The cover latching mechanism of claim 1, wherein the latching portion of the housing is hook-shaped, having a body perpendicularly extending from the housing and a projection formed at a distal end of the body, the locking portion of the cover including two arms formed at two opposite ends of one side of the cover to define a cutout therebetween, at least one of the arms having a projection extending into the cutout, and the projection of the latching portion can extend in the cutout and resist the projection of the locking portion.

4. The cover latching mechanism of claim 3, wherein the latching portion further includes a body perpendicularly extending from the housing and a projection formed at a distal end of the body, the two projections of the latching portion extend away from each other, the other arm of the locking portion has a projection extending into the cutout, and the two projections of the locking portion face towards each other.

5. The cover latching mechanism of claim 1, wherein the hinge portion of the housing includes a barrel defining an axle hole, the connecting portion of the cover is barrel-shaped and defines an axle hole, and the mounting member includes an axle mounted in the two axle holes.

6. The cover latching mechanism of claim 5, wherein the mounting member further includes a positioning pin perpendicularly extending from a distal end of the axle of the mounting member, the barrel of the hinge portion defines a pin hole in one side thereof, the pin hole communicates with the axle hole of the barrel, and the positioning pin is received in the pin hole.
